(19) United States
(12) Patent Application Publication
(10) Pub. No.: US 2026/0252927 A1
(43) Pub. Date: Aug. 27, 2026

(54) PROBABILISTIC BIT DEVICE HAVING VARIABLE REFERENCE VOLTAGE AND RELATED METHODS

(71) Applicant: Taiwan Semiconductor Manufacturing Company Limited, Hsin-Chu (TW)

(72) Inventors: Yu-Sheng CHEN, Taoyuan City (TW); Yi-Hsuan CHEN, Taoyuan City (TW); Yi Ching ONG, Hsinchu (TW); Kuo-Ching HUANG, Hsinchu City (TW)

(21) Appl. No.: 19/059,357

(22) Filed: Feb. 21, 2025

(51) Int. Cl. G06N 7/01; G11C 11/16; H10N 50/10

(52) U.S. Cl. CPC G06N 7/01; G11C 11/1673; G11C 11/1697; H10N 50/10

(57) ABSTRACT

A device is provided. The device includes: a sense amplifier having a first input, a second input, and an output. The sense amplifier, in operation: receives a first voltage at the first input; receives a second voltage at the second input; and generates a probabilistic output voltage at the output. The device includes: a first voltage generator including a first magnetic tunnel junction, the first voltage generator, in operation, generating the first voltage; and a second voltage generator including a variable resistor, the second voltage generator, in operation, generating the second voltage.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, and 1G illustrate schematic views of probabilistic bit devices, in accordance with some embodiments.

FIGS. 1H, 1I, 1J, 1K, and 1L illustrate schematic views of resistor devices of the probabilistic bit devices, in accordance with some embodiments.

FIGS. 2A and 2B are diagrams illustrating probabilistic logic devices, in accordance with some embodiments.

FIGS. 3A and 3B are diagrams illustrating probabilistic logic devices, in accordance with some embodiments.

FIGS. 4A and 4B are diagrams illustrating probabilistic logic devices, in accordance with some embodiments.

FIG. 5 is a diagram illustrating a probabilistic logic device, in accordance with some embodiments.

FIG. 6 illustrates a method of generating a probabilistic output, in accordance with some embodiments.

FIG. 7 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, probabilistic circuits include probabilistic bit (p-bit) devices. The probabilistic circuits can perform probabilistic operations in which an output of the probabilistic circuit is clamped and reverse logic gates that include the probabilistic bit devices are operated to determine likely inputs that as associated with the clamped output. Examples of probabilistic functions that can be performed by probabilistic circuits include decryption (e.g., integer factorization), maximum cut, subset sum, digital signal processing, and the like.

Some probabilistic bit devices include a magnetic tunnel junction (MTJ) device, which can have materials, dimensions, and/or shape that result in low magnetic anisotropy energy barriers, making the magnetization state of a free layer thereof inherently unstable at an operating temperature, such as room temperature. An MTJ voltage of the MTJ device can be compared with a reference voltage by a sense amplifier to determine whether a logic level of the MTJ device is logic high or logic low. Due to process variation across an array of MTJ devices, behavior of the MTJ voltages thereof may vary, which can result in determination errors when compared against the reference voltage.

In embodiments of the disclosure, each p-bit device can include a variable resistor device that has one or more fixed resistors and at least one variable resistor, such that the reference voltage for each p-bit device may be selected by controlling resistance value of the respective variable resistor(s). In some embodiments, different control voltages are applied to the respective variable resistor(s) associated with the different p-bit devices. As a result, the p-bit devices can be read out precisely, even in the presence of bit-to-bit non-uniformity. In some embodiments, generation of the resistance value of the variable resistor device can be mainly generated by the fixed resistor(s) and may be modulated by the variable resistor(s). For example, a first variable resistor may be connected in parallel with the fixed resistor(s) and a second variable resistor may be connected in series with the fixed resistor(s). Reducing first resistance value of the first variable resistor may reduce the resistance value of the variable resistor device, and increasing second resistance value of the second variable resistor may increase the resistance value of the variable resistor device.

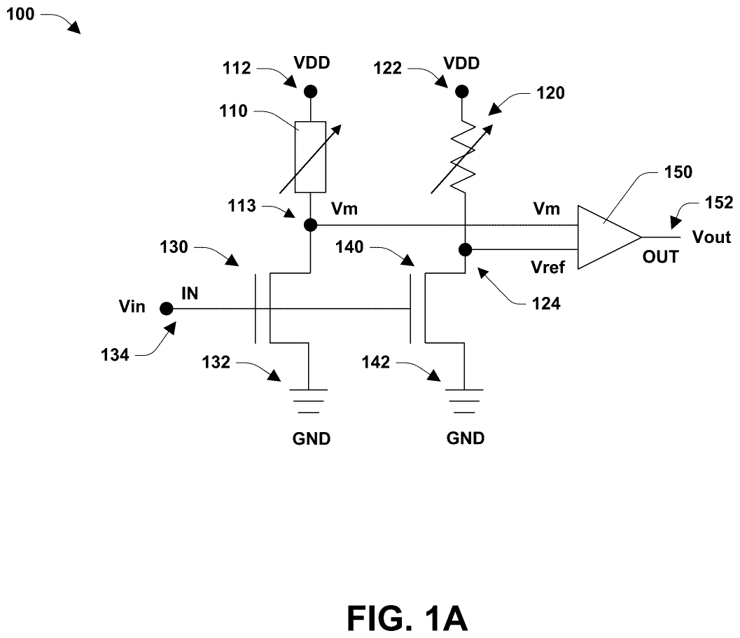

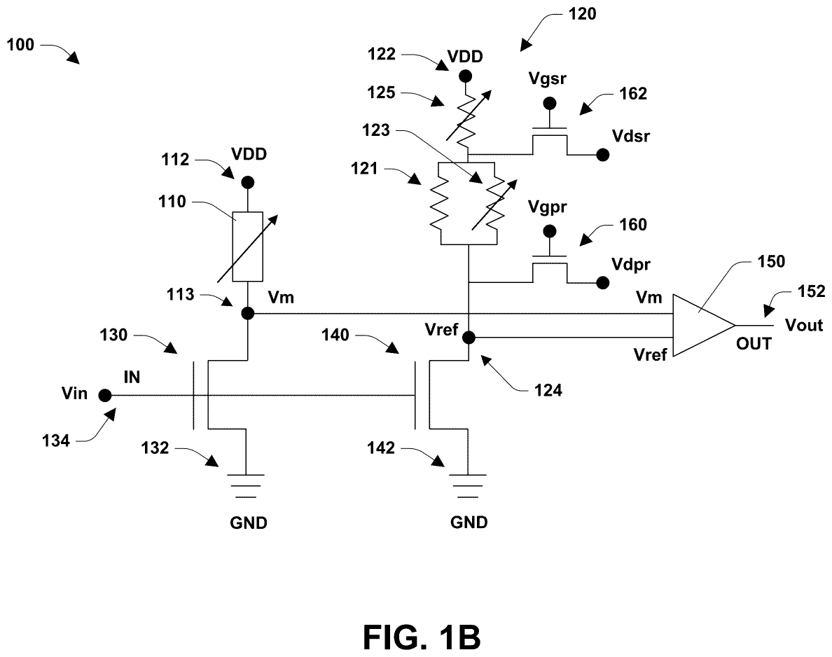

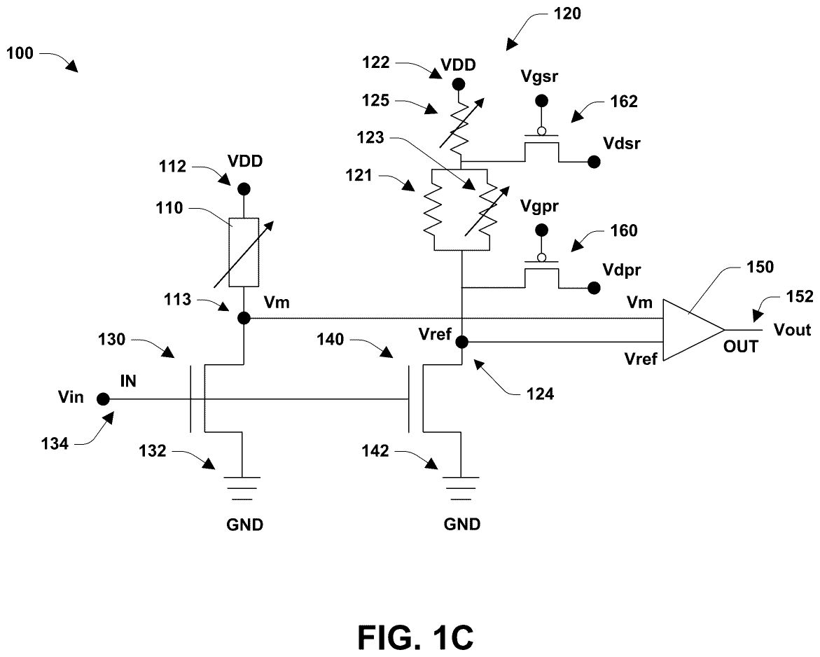

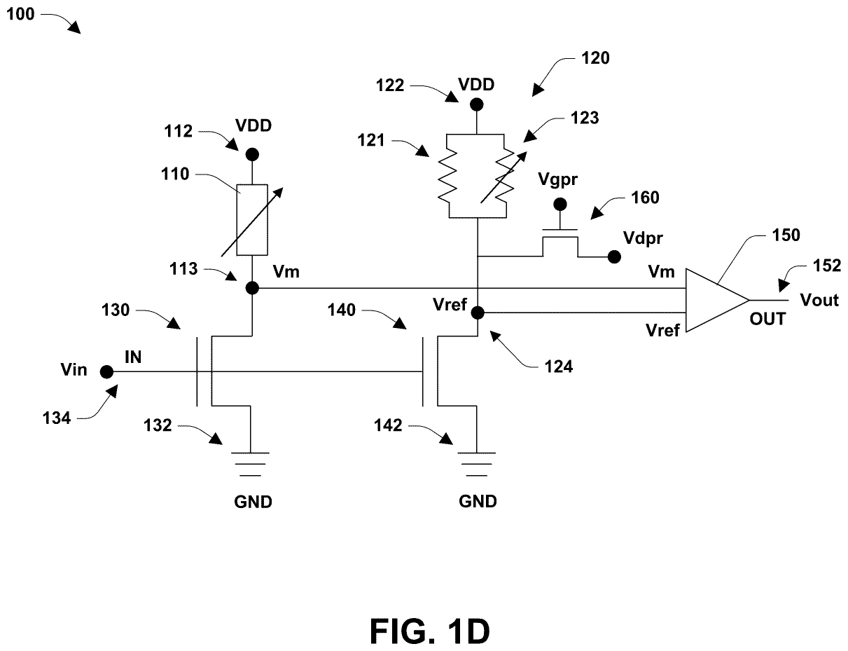

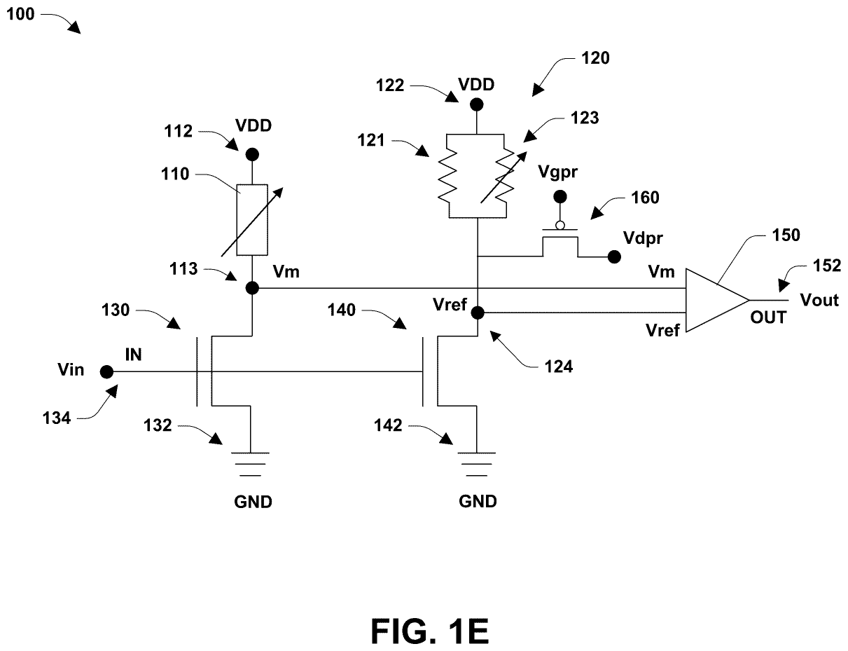

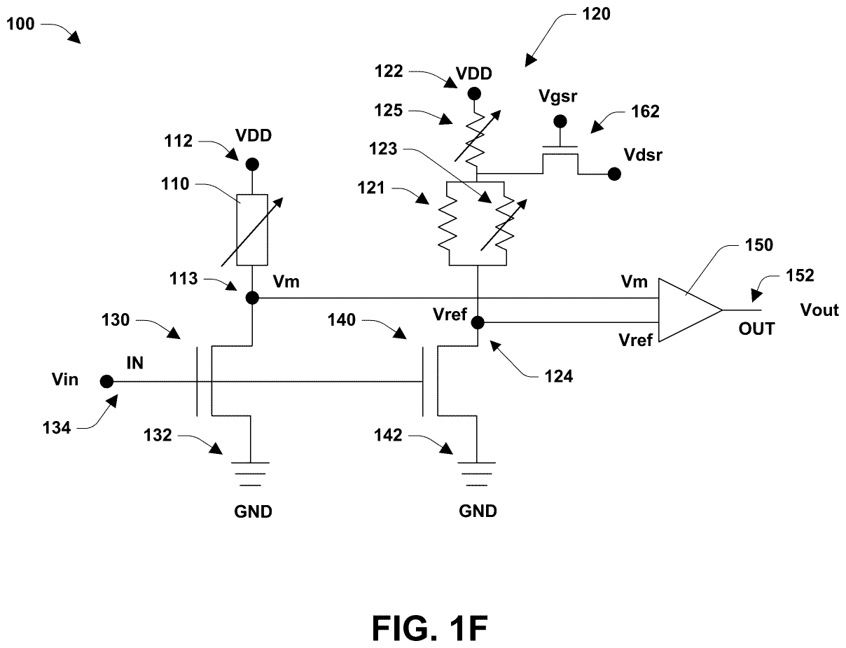

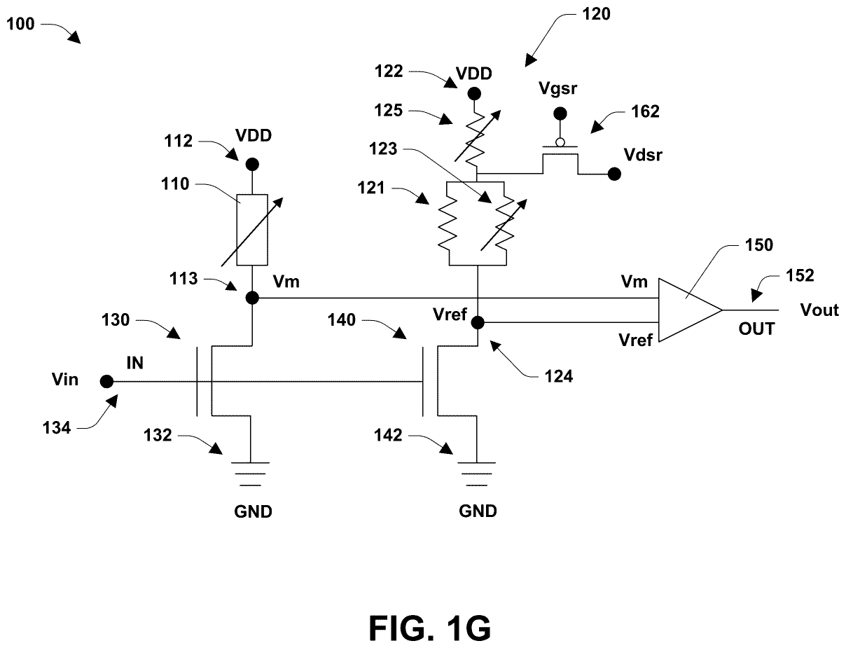

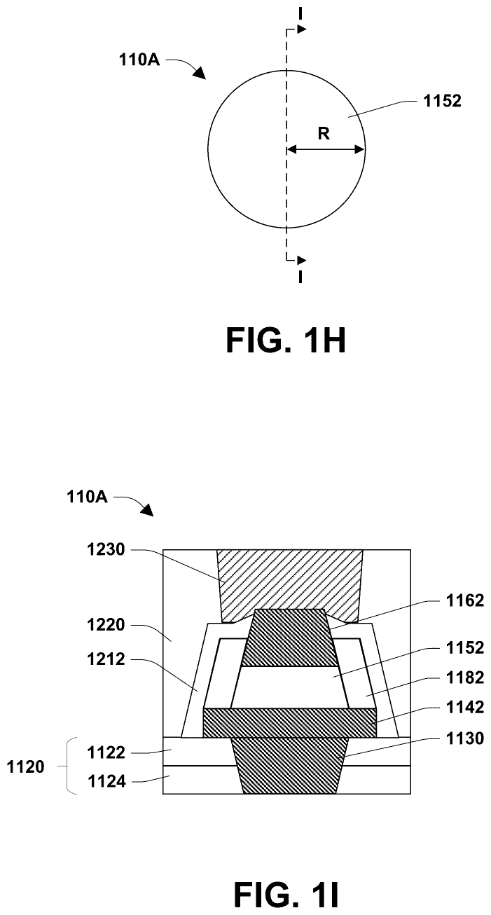

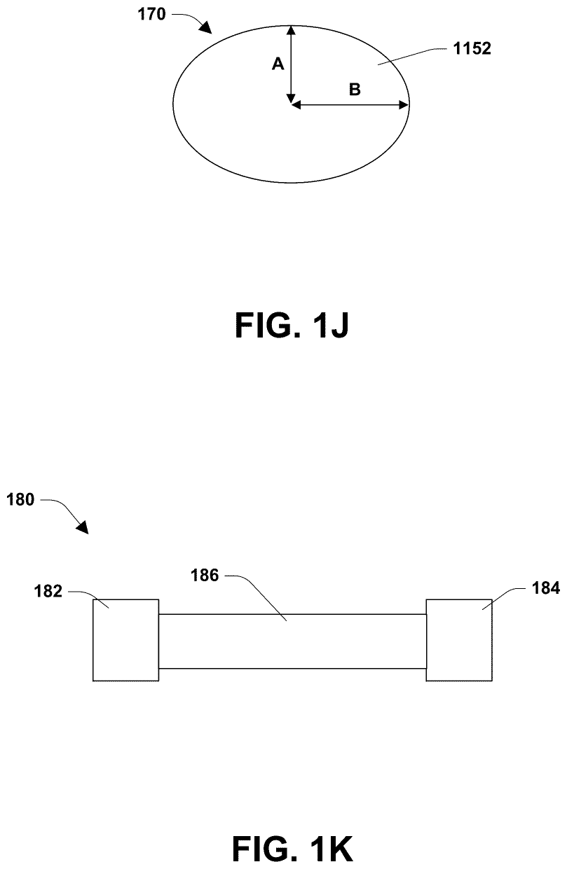

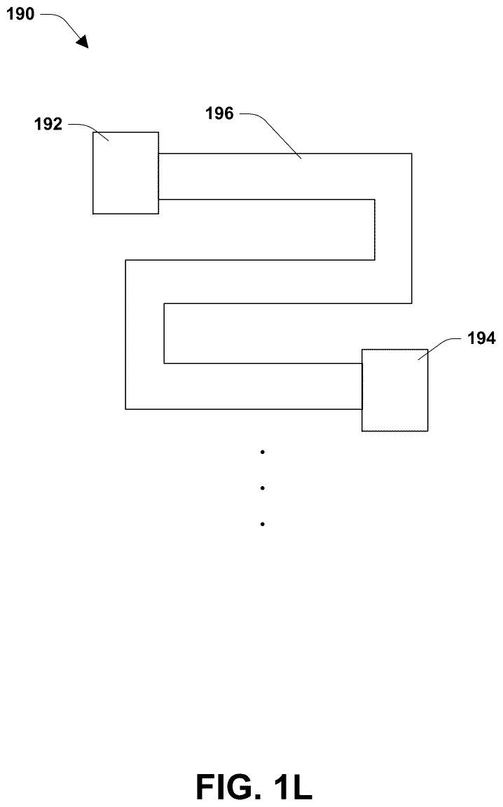

FIGS. 1A, 1B, 1C, 1D, 1E, 1F, and 1G illustrate schematic views of probabilistic bit (p-bit) devices 100, in accordance with some embodiments.

In FIG. 1A, the probabilistic bit device 100 includes a sense amplifier 150 that is operable, in some embodiments, to generate an output signal, such as an output voltage Vout, in response to a magnetic tunnel junction (MTJ) voltage Vm and a reference voltage Vref. In some embodiments, the sense amplifier 150 can be or include a differential sense amplifier (DSA), a current sense amplifier (CSA), a charge transfer sense amplifier, a voltage sense amplifier (VSA), a pre-charged sense amplifier (PCSA), or the like. In the embodiment depicted in FIG. 1A, the sense amplifier 150 includes a differential sense amplifier, which can be or include a cross-coupled latch sense amplifier (e.g., n-type or p-type), a current-mode sense amplifier, a voltage mode sense amplifier with active loads, a charge transfer sense amplifier, or the like. The sense amplifier 150 includes: a first input that is electrically connected to a node 113; a second input that is electrically connected to a node 124; and an output (OUT) 152. In some embodiments, in response to the MTJ voltage Vm exceeding the reference voltage Vref, the sense amplifier 150 generates the output voltage Vout as a high voltage, and in response to the reference voltage Vref exceeding the MTJ voltage Vm, the sense amplifier 150 generates the output voltage Vout as a low voltage. The high voltage exceeds the low voltage. In some embodiments, the low voltage exceeds the high voltage.

The probabilistic bit device 100 includes a first MTJ 110 and a first current source 130 that is electrically connected to the first MTJ 110. The first current source 130 generates first current that is conducted by the first MTJ 110, which results in generation of the MTJ voltage Vm. The first MTJ 110 can switch between a parallel state and an antiparallel state, in which a pinned layer thereof and a free layer thereof have magnetization directions that are parallel in the parallel state and antiparallel in the antiparallel state. Electrical resistance of the first MTJ 110 in the antiparallel state can exceed that of the first MTJ 110 in the parallel state. In the embodiment depicted in FIG. 1A, a first terminal of the first MTJ 110 is electrically connected to a first voltage source 112 that provides a first supply voltage VDD, and a second terminal of the first MTJ 110 is electrically connected to a first input of the sense amplifier 150 and a first terminal of the first current source 130 at a node 113. The MTJ voltage Vm, in some embodiments, is substantially equal to the first supply voltage VDD minus voltage across the first MTJ 110, which is substantially the product of the first current and the electrical resistance of the first MTJ 110. As such, the MTJ voltage Vm in the parallel state can exceed that of the MTJ voltage Vm in the antiparallel state. The first MTJ 110 and the first current source 130 can be referred to collectively as a “first voltage generator” that generates the MTJ voltage Vm.

The first MTJ 110 has magnetization dynamics that lend to probabilistic behavior of the MTJ voltage Vm generated thereby. In some embodiments, material, structure or both of the first MTJ 110 may be selected to reduce magnetic anisotropy energy barriers thereof, resulting in magnetization state of the free layer having increased instability at an operating temperature thereof (e.g., room temperature). In some embodiments, shape or profile of the first MTJ 110 may be circular. The first MTJ 110 may have the free layer and the pinned layer arranged in a stack along a first direction (e.g., a vertical direction). The profile of the first MTJ 110 that is circular may be in a plane (e.g., a horizontal plane) that is transverse (e.g., perpendicular to) the first direction. In some embodiments, diameter of the profile of the first MTJ 110 can be in a range of about 20 nanometers (nm) to about 100 nm and radius of the profile of the first MTJ 110 can be in a range of about 10 nm to about 50 nm. The first MTJ 110 may be positioned in an interconnect layer that is overlying a device layer in which the sense amplifier 150 is positioned. For example, the interconnect layer can be a back-end-of-line (BEOL) interconnect layer that is overlying a device layer in which transistors, such as nanoscale transistors, are positioned. The sense amplifier 150 can include the nanoscale transistors. In some embodiments, material of the free layer can be or include CoFeB, CoFe, FeB, CoB, NiFe, NiFeMo, or the like. In some embodiments, material of the fixed or pinned layer can be or include one or more multilayers, such as Ni/Fe, Ni/Co, Co/Pt, Fe/Pt, Co/Pd, Fe/Pd, or the like. A barrier layer of the first MTJ 110 that is positioned between the free layer and the pinned layer can be or include a dielectric material, such as MgO, Al₂O₃, or the like. An MTJ 110A that can be an embodiment of the first MTJ 110 is described in greater detail with reference to FIGS. 1H and 1I.

In some embodiments, the first current source 130 is a metal-oxide-semiconductor (MOS) transistor, such as an n-type MOS (NMOS) transistor. In some embodiments, the first current source 130 has a first source/drain that is electrically connected to the node 113, a second source/drain that is electrically connected to a second voltage source 132, and a gate that is electrically connected to an input (IN) 134. “Source/drain” may refer to a source or a drain, individually or collectively, dependent upon the context. In some embodiments, the second voltage source 132 is ground. The first current source 130 can receive an input voltage Vin at the input 134. In response to the input voltage Vin, the first current source 130 can conduct electrical current (or “first current”) through the first source/drain and the second source drain via a channel established therebetween. Magnitude of the electrical current can be associated with magnitude of the input voltage Vin. For example, the electrical current can increase with increase of the input voltage Vin.

The p-bit device 100 includes a variable resistor device 120 and a second current source 140. The second current source 140 can be similar in most respects to the first current source 130. For example, the second current source 140 can include a MOS transistor, such as an NMOS transistor. The second current source 140 can have a first source/drain electrically connected to the node 124 (e.g., the second input of the sense amplifier 150), a second source/drain electrically connected to a fourth voltage source 142 (e.g., ground), and a gate electrically connected to the input 134. The second current source 140, in operation, generates electrical current (or “second current”) that is conducted by the variable resistor device 120, which results in generation of the reference voltage Vref at the second input of the sense amplifier 150. In some embodiments, the first current exceeds the second current. In some embodiments, the second current exceeds the first current. In some embodiments, the first current is substantially equal to the second current. The variable resistor device 120 and the second current source 140 can be referred to collectively as a “second voltage generator” that generates the reference voltage Vref.

The variable resistor device 120 has electrical resistance that can be selected via one or more electrical signals. In some embodiments, the variable resistor 120 has a first terminal that is electrically connected to a third voltage source 122, and a second terminal that is electrically connected to the node 124. The third voltage source 122 can be the same as the first voltage source 112, in some embodiments. For example, the third voltage source 122 may supply the first supply voltage VDD. The reference voltage Vref can be substantially equal to the first supply voltage VDD minus the product of the electrical current supplied by the second current source 140 and the electrical resistance of the variable resistor device 120. Reducing the electrical resistance of the variable resistor device 120 increases the reference voltage Vref. Increasing the electrical resistance of the variable resistor device 120 reduces the reference voltage Vref. Embodiments of the variable resistor device 120 are described in greater detail with reference to FIGS. 1B-1G.

FIG. 1B illustrates a schematic view of the p-bit device 100, in accordance with some embodiments. The p-bit device 100 of FIG. 1B is similar in most respects to the p-bit device 100 of FIG. 1A, and like reference numerals refer to like elements.

In FIG. 1B, the variable resistor device 120 includes at least one fixed resistor 121, at least one first variable resistor 123, and at least one second variable resistor 125. The fixed resistor 121 has a first end electrically connected to the node 124 and a second end electrically connected to a second end of the second variable resistor 125. The first variable resistor 123 has a first end electrically connected to the node 124 and a second end electrically connected to a second end of the second variable resistor 125. For example, the fixed resistor 121 and the first variable resistor 123 are connected in parallel to each other. The second variable resistor 125 has a first end electrically connected to the third voltage source 122 and the second end thereof is connected to the second ends of the fixed resistor 121 and the first variable resistor 123. For example, the second variable resistor 125 and the parallel connection of the fixed resistor 121 and the first variable resistor 123 are connected in series to each other.

The fixed resistor 121 can be a metal resistor that is positioned in a metal layer (e.g., a BEOL layer) overlying the device layer in which the sense amplifier 150 is positioned. In some embodiments, the fixed resistor 121 has shape that is square, rectangular or the like. In some embodiments, the fixed resistor 121 is or includes a material, such as a metal material that can include one or more of TiN, TaN, Al, W, TiW, combinations thereof, or the like. A fixed resistor 190 that can be an embodiment of the fixed resistor 121 is described with reference to FIG. 1L.

Each of the first variable resistor 123 (or “parallel variable resistor 123”) and the second variable resistor 125 (or “serial variable resistor 125”) is or includes one or more of an MTJ resistor, a polysilicon resistor, an n-well resistor, a p-well resistor, a dielectric resistor, combinations thereof or the like. In some embodiments, the first variable resistor 123 and/or the second variable resistor 125 is an MTJ resistor (or “second MTJ”) that has elliptical or rectangular shape that is different than shape of the first MTJ 110 (e.g., circular shape). In some embodiments, ratio of cross-sectional or profile area of the second MTJ over that of the first MTJ 110 is in a range of about 0.4 to about 0.7. In some embodiments, ratio of minor radius of the second MTJ over radius of the first MTJ 110 can be in a range of about 0.4 to about 0.5. In some embodiments, ratio of major radius of the second MTJ over the radius of the first MTJ 110 can be in a range of about 1.0 to about 1.5. In some embodiments, the second MTJ can be positioned in one or more metal layers (e.g., BEOL layers) of the interconnect structure overlying the device layer in which the sense amplifier 150 is positioned. In some embodiments, the first variable resistor 123 and/or the second variable resistor 125 is a polysilicon resistor, an n-well resistor, a p-well resistor, a dielectric resistor. In some embodiments, shape of the first variable resistor 123 and/or the second variable resistor 125 can be square, rectangular, or another suitable shape. In some embodiments, material of the first variable resistor 123 and/or the second variable resistor 125 can be Si, doped Si, Ge, doped Ge, SiGe, doped SiGe, SiO₂, TiO₂, HfO₂, ZrO₂, Al₂O₃, Ta₂O₅, combinations thereof, or the like. In some embodiments, the first variable resistor 123 and/or the second variable resistor 125 can be positioned in an interconnect layer, such as a BEOL layer. In some embodiments, the first variable resistor 123 and/or the second variable resistor 125 can be positioned in the device layer, such as a front-end-of-line (FEOL) layer. A variable resistor 170 and a variable resistor 180 that can each be an embodiment of the first variable resistor 123, the second variable resistor 125, or both are described with reference to FIGS. 1J and 1K.

In operation, electrical resistances (or simply, “resistances” or “impedances”) of the first variable resistor 123 and the second variable resistor 125 can be selected by voltage selecting circuit, such as a controller. The controller may be integrated in a same integrated circuit (IC) device in which the p-bit device 100 is positioned or may be external to the IC device. For example, the electrical resistances may be selected in a manufacturing stage that is prior to packaging of the IC device, prior to bonding of the IC device to a substrate (e.g., a printed circuit board or another IC device), or following bonding of the IC device to the substrate. The electrical resistances, once selected, may be fixed, such as by use of integrated fuse circuits. In some embodiments, the electrical resistances remain selectable substantially throughout the lifetime of the IC device.

Selection of the electrical resistances may be performed by selecting at least one voltage signal that is applied to the variable resistor device 120. As depicted in FIG. 1B, the resistance(s) of the first variable resistor 123 and the second variable resistor 125 are controlled by at least two voltage signals that include a first voltage signal Vdpr and a second voltage signal Vdsr. The first voltage signal Vdpr can be applied to the first end of the first variable resistor 123 via a first switch 160. The second voltage signal Vdsr can be applied to the second ends of the first variable resistor 123 and the second variable resistor 125 by a second switch 162. The first switch 160 and the second switch 162 can each be an NMOS transistor. The first switch 160 can be turned on to conduct electrical current by a first gate voltage signal Vgpr, thereby transmitting the first voltage signal Vdpr to the first end of the first variable resistor 123. The second switch 162 can be turned on to conduct electrical current by a second gate voltage signal Vgsr, thereby transmitting the second voltage signal Vdsr to the second ends of first variable resistor 123 and the second variable resistor 125. In some embodiments, the first supply voltage VDD exceeds the second voltage signal Vdsr, which exceeds the first voltage signal Vdpr, which exceeds the reference voltage Vref.

In operation, integrated resistors, such as the first variable resistor 123 and the second variable resistor 125, that have variable resistance based on the applied voltage can have electrical resistances that are selected via one or more mechanisms and structures. As described above, the first variable resistor 123 and the second variable resistor 125 can each be the elliptical or rectangular second MTJ. The second MTJ includes two ferromagnetic layers separated by a thin insulating barrier (tunnel barrier). The resistance of the second MTJ can change due to the magnetoresistance effect where relative orientation of magnetization in the two ferromagnetic layers affects the tunneling probability of electrons. Applying a voltage, such as the first voltage signal Vdsr and/or the second voltage signal Vdpr, can change the magnetic state through spin-transfer torque (STT), where the spin-polarized current can switch the magnetization of one layer relative to the other, thus changing resistance.

As described above, the first variable resistor 123 and the second variable resistor 125 can each be a polysilicon resistor, an n-well resistor, a p-well resistor, a dielectric resistor or the like. The polysilicon resistor can be doped to alter conductivity thereof. Applying an electric field or voltage across the polysilicon resistor, such as by the first voltage signal Vdsr and/or the second voltage signal Vdpr, can induce changes in carrier concentration or mobility through field-effect modulation. The n-well or p-well resistor can be or include regions having selected doping types. The resistance of the n-well or p-well resistor can change due to the field-effect where the applied voltage, such as the first voltage signal Vdsr and/or the second voltage signal Vdpr, can deplete or enhance the carrier concentration in the well, thus changing resistance thereof. In the dielectric resistor, structures where the resistance thereof is through a dielectric layer can include resistive switching or memristive effects. In materials exhibiting resistive switching, the resistance state can change based on the voltage applied, such as via the first voltage signal Vdsr and/or the second voltage signal Vdpr, where high or low resistance states correspond to different voltage thresholds or polarities. This can be due to filament formation or phase changes in the dielectric layer.

Reducing the resistance of the first variable resistor 123 via the first voltage signal Vdsr and/or the second voltage signal Vdpr can reduce the resistance of the variable resistor device 120, thereby increasing the reference voltage Vref. Increasing the resistance of the first variable resistor 123 via the first voltage signal Vdsr and/or the second voltage signal Vdpr can increase the resistance of the variable resistor device 120, thereby reducing the reference voltage Vref. Increasing the resistance of the second variable resistor 125 via the second voltage signal Vdpr can increase the resistance of the variable resistor device 120, thereby reducing the reference voltage Vref. Reducing the resistance of the second variable resistor 125 via the second voltage signal Vdpr can reduce the resistance of the variable resistor device 120, thereby increasing the reference voltage Vref. As such, in response to the first MTJ 110 generating the MTJ voltage Vm at an increased voltage level, the reference voltage Vref can be increased via the first voltage signal Vdsr and/or the second voltage signal Vdpr. In response to the first MTJ 110 generating the MTJ voltage Vm at a reduced voltage level, the reference voltage Vref can be reduced via the first voltage signal Vdsr and/or the second voltage signal Vdpr.

FIG. 1C illustrates a schematic view of the p-bit device 100, in accordance with some embodiments. The p-bit device 100 of FIG. 1C is similar in most respects to the p-bit device 100 of FIG. 1B, and like reference numerals refer to like elements. In some embodiments, the first switch 160 and the second switch 162 can be PMOS transistors instead of being NMOS transistors. In some embodiments, one of the first switch 160 and the second switch 162 can be a PMOS transistor and the other of the first switch 160 and the second switch 162 can be an NMOS transistor.

FIG. 1D illustrates a schematic view of the p-bit device 100, in accordance with some embodiments. The p-bit device 100 of FIG. 1D is similar in most respects to the p-bit device 100 of FIG. 1B, and like reference numerals refer to like elements. In some embodiments, the second variable resistor 125 and the second switch 162 are not included or are optional. In some embodiments, the second ends of the first variable resistor 123 and the fixed resistor 121 can be directly electrically connected to the third voltage source 122 instead of being electrically connected through the second variable resistor 125. Resistance of the first variable resistor 123 is selected based on the first supply voltage VDD and the first voltage signal Vdpr.

FIG. 1E illustrates a schematic view of the p-bit device 100, in accordance with some embodiments. The p-bit device 100 of FIG. 1E is similar in most respects to the p-bit device 100 of FIG. 1D, and like reference numerals refer to like elements. In some embodiments, the first switch 160 can be a PMOS transistor instead of being the NMOS transistor depicted in FIG. 1D.

FIG. 1F illustrates a schematic view of the p-bit device 100, in accordance with some embodiments. The p-bit device 100 of FIG. 1F is similar in most respects to the p-bit device 100 of FIG. 1B, and like reference numerals refer to like elements. In some embodiments, the first switch 160 is not included, such that voltage at the first end of the first variable resistor 123 is not selected via the first voltage signal Vdpr. In some embodiments, the voltage of the first end of the first variable resistor 123 is substantially equal to the reference voltage Vref. As such, resistance of the first variable resistor 123 is selected via the second voltage signal Vdsr.

FIG. 1G illustrates a schematic view of the p-bit device 100, in accordance with some embodiments. The p-bit device 100 of FIG. 1B is similar in most respects to the p-bit device 100 of FIG. 1A, and like reference numerals refer to like elements. In some embodiments, the second switch 162 can be a PMOS transistor instead of being the NMOS transistor depicted in FIG. 1F.

FIGS. 1H, 1I, 1J, 1K, and 1L illustrate schematic views of an MTJ 110A, variable resistors 170, 180, and fixed resistor 190 of the probabilistic bit devices, in accordance with some embodiments.

FIGS. 1H and 1I illustrate schematic views of the MTJ 110A, which can be an embodiment of the first MTJ 110 described with reference to FIGS. 1A-1G. FIG. 1I illustrates a cross-sectional view of the MTJ 110A along cross-sectional line I-I of FIG. 1H.

In FIG. 1H, the MTJ 110A can have a circular profile in a plan view. The MTJ 110A can have radius R, which can be in a range of about 10 nm to about 50 nm. The radius R can be associated with a resistive switching element 1152, in some embodiments.

In FIG. 1I, a resistance switching element 1152 and a top electrode 1162 are positioned over the bottom electrode 1142 in a sequence. In some embodiments, the resistance switching element 1152 may be a magnetic tunnel junction (MTJ) structure. For example, the resistance switching element 1152 can include one or more of a first magnetic layer, a tunnel barrier layer, and a second magnetic layer positioned in sequence over the bottom electrode 1142.

In some embodiments, the first magnetic layer includes an anti-ferromagnetic material (AFM) layer over the bottom electrode 1142 and a ferromagnetic pinned layer over the AFM layer. In some embodiments, the AFM layer includes a multilayer of: (i) Ni and Fe, (ii) Ni and Co, (iii) Co and Pt, (iv) Fe and Pt, (v) Co and Pd, (vi) Fe and Pd, or the like. The AFM layer may be formed by one or more operations that can include sputtering, PVD, ALD, e-beam or thermal evaporation, or the like.

The ferromagnetic pinned layer can be a permanent magnet. Magnetic moment of the ferromagnetic pinned layer can be pinned by the AFM layer and may not be substantially changed during operation of the MTJ stack. In some embodiments, the ferromagnetic pinned layer includes cobalt-iron-boron (CoFeB), CoFeTa, NiFe, Co, CoFe, CoPt, or an alloy of Ni, Co and Fe. The ferromagnetic pinned layer may be formed by one or more operations that can include sputtering, PVD, ALD, e-beam or thermal evaporation, or the like. In some embodiments, the ferromagnetic pinned layer includes a multilayer structure.

The tunnel barrier layer is positioned over the first magnetic layer and can also be referred to as a tunneling layer. In some embodiments, the tunnelling layer has thickness that allows electrons to tunnel therethrough when a voltage is applied to the MTJ stack. In some embodiments, the tunnel barrier layer includes magnesium oxide (MgO), aluminum oxide (Al₂O₃), aluminum nitride (AlN), aluminum oxynitride (AlON), hafnium oxide (HfO₂), zirconium oxide (ZrO₂), combinations thereof or the like. The tunnel barrier layer may be formed by one or more operations that include sputtering, PVD, ALD, e-beam or thermal evaporation, or the like.

The second magnetic layer is positioned over the tunnel barrier layer, and can be referred to as a ferromagnetic free layer. Magnetic moment of the second magnetic layer is not pinned due to absence of anti-ferromagnetic material therein. As such, magnetic orientation of the second magnetic layer can be selected. In some embodiments, direction of the magnetic moment of the second magnetic layer can rotate parallel or anti-parallel to the pinned direction of the ferromagnetic pinned layer. The second magnetic layer may include a ferromagnetic material similar to the material in the ferromagnetic pinned layer in the first magnetic layer, such as CoFeB, CoFe, FeB, CoB, NiFe, NiFeMo, or the like. In some embodiments, the second magnetic layer can be formed by one or more operations that include sputtering, PVD, ALD, e-beam or thermal evaporation, or the like.

A top electrode 1162 is positioned over the resistance switching element 1152. The top electrode 1162 includes a conductive material. In some embodiments, the top electrode 1162 includes a metal, such as tungsten (W), titanium (Ti), tantalum (Ta), platinum (Pt), ruthenium (Ru), aluminum (Al), copper (Cu), the like or combinations thereof, which can be formed by one or more operations that include sputtering, PVD, or the like.

A dielectric layer 1120 is positioned under the bottom electrode 1142. The dielectric layer 1120 can include silicon carbide (SiC), silicon oxynitride (SiON), silicon nitride (SiN), silicon dioxide, the like, or combinations thereof. The dielectric layer 1120 may be a single-layered structure or a multi-layered structure. In the embodiment depicted in FIG. 1I, the dielectric layer 1120 includes a silicon carbide layer 1122 and a silicon-rich oxide (SRO) layer 1124 over the silicon carbide layer 1122. The dielectric layer 1120 may be formed by chemical vapor deposition (CVD), atomic layer deposition (ALD), physical vapor deposition (PVD), the like, and/or a combination thereof.

A bottom electrode via (BEVA) 1130 is positioned in the dielectric layer 1120. In some embodiments, the BEVA 1130 is electrically connected to an underlying electrical component, such as a transistor, through one or more metallization patterns. In some embodiments, the BEVA 1130 is a multi-layered structure and includes, for example, a diffusion barrier layer and a metal layer positioned in a recess in the diffusion barrier layer. In some embodiments, the diffusion barrier layer is a titanium nitride (TiN) layer or a tantalum nitride (TaN) layer. Formation of the diffusion barrier layer may be by CVD, PVD, ALD, the like, and/or a combination thereof. In some embodiments, the metal layer is or includes titanium (Ti), tantalum (Ta), platinum (Pt), ruthenium (Ru), tungsten (W), aluminum (Al), copper (Cu), TiN, TaN, the like, and/or combinations thereof. Formation of the metal layer may be by CVD, PVD, ALD, the like, and/or a combination thereof.

A first spacer 1182 may be or include non-magnetic material, such as a dielectric material. The first spacer 1182 is positioned on the bottom electrode 1142, and is immediately adjacent the resistance switching element 1152 and the top electrode 1162. The first spacer 1182 may include SiN, SiC, SiON, silicon oxycarbide (SiOC), the like, and/or combinations thereof. The first spacer 1182 may be formed by CVD, PVD, ALD, the like, and/or combinations thereof.

A second spacer 1212 may be or include non-magnetic material, such as a dielectric material. The second spacer 1212 is positioned on the silicon carbide layer 1122, and is adjacent the bottom electrode 1142, the first spacer 1182 and the top electrode 1162. The second spacer 1212 may include SiN, SiC, SiON, silicon oxycarbide (SiOC), the like, and/or combinations thereof. The second spacer 1212 may be formed by CVD, PVD, ALD, the like, and/or combinations thereof.

An interlayer dielectric (ILD) layer 1220 is positioned over the second spacer 1212 and the silicon carbide layer 1122. In some embodiments, the ILD layer 1220 includes silicon oxide, fluorinated silica glass (FSG), carbon doped silicon oxide, tetra-ethyl-ortho-silicate (TEOS) oxide, phosphosilicate glass (PSG), borophosphosilicate glass (BPSG), Black Diamond® (Applied Materials of Santa Clara, Calif.), amorphous fluorinated carbon, low-k dielectric material, the like or combinations thereof.

A metallization pattern 1230 is positioned in the ILD layer 1220. The metallization pattern 1230 can include a conductive line connected to the top electrode 1162, and can be in direct contact with the top electrode 1162. In some embodiments, the metallization pattern 1230 may include one or more conductive vias, conductive lines, or a combination thereof. The metallization pattern 1230 may be formed by etching an opening and/or trench in the ILD layer 1220, then depositing one or more metals (e.g., copper) in the opening and/or trench.

FIG. 1J illustrates a schematic plan view of a variable resistor 170, which can be referred to as the MTJ 170. The variable resistor 170 can be an embodiment of the first variable resistor 123, the second variable resistor 125, or both. The variable resistor 170 has an elliptical or rectangular shape that is different than shape of the MTJ 110A (e.g., circular shape). The variable resistor 170 is similar in most respects to the MTJ 110A. Size and shape of the resistive switching element 1152 of the variable resistor 170 is different than that of the MTJ 110A.

In some embodiments, ratio of cross-sectional or profile area of the variable resistor 170 over that of the MTJ 110A is in a range of about 0.4 to about 0.7. In some embodiments, ratio of minor radius A of the variable resistor 170 over radius R of the MTJ 110A can be in a range of about 0.4 to about 0.5. In some embodiments, ratio of major radius B of the variable resistor 170 over the radius R of the MTJ 110A can be in a range of about 1.0 to about 1.5. In some embodiments, the variable resistor 170 can be positioned in one or more metal layers (e.g., BEOL layers) of the interconnect structure overlying the device layer in which the sense amplifier 150 is positioned.

FIG. 1K illustrates a schematic view of a variable resistor 180, which can be an embodiment of the first variable resistor 123, the second variable resistor 125, or both. In some embodiments, the variable resistor 180 is a polysilicon resistor, an n-well resistor, a p-well resistor, a dielectric resistor. The variable resistor 180 includes a resistive element 186 that is elongated and is in contact with a first pad 182 on one end and with a second pad 184 on another end. In some embodiments, shape of the variable resistor 180 is square, rectangular (as shown), or another suitable shape. In some embodiments, material of the variable resistor 180 is Si, doped Si, Ge, doped Ge, SiGe, doped SiGe, SiO2, TiO2, HfO2, ZrO2, Al2O3, Ta2O5, combinations thereof, or the like. In some embodiments, the variable resistor 180 is positioned in an interconnect layer, such as a BEOL layer. In some embodiments, the variable resistor 180 is positioned in the device layer, such as a front-end-of-line (FEOL) layer.

FIG. 1L illustrates a schematic view of a fixed resistor 190, which can be an embodiment of the fixed resistor 121. The fixed resistor 190 can be a metal resistor that is positioned in a metal layer (e.g., a BEOL layer) overlying the device layer in which the sense amplifier 150 is positioned. In some embodiments, the fixed resistor 190 has shape that is square, rectangular or the like. In some embodiments, the fixed resistor 190 is or includes a material, such as a metal material that can include one or more of TiN, TaN, Al, W, TiW, combinations thereof, or the like. For example, the fixed resistor 190 can include a resistive element 196 that includes the metal material and extends from a first pad 192 to a second pad 194. The resistive element 196 may include an S-shape that increases effective length of the resistive element 196 within a same area. The S-shape may be repeated, such that the resistive element 196 includes at least two S-shapes that extend from the first pad 192 to the second pad 194.

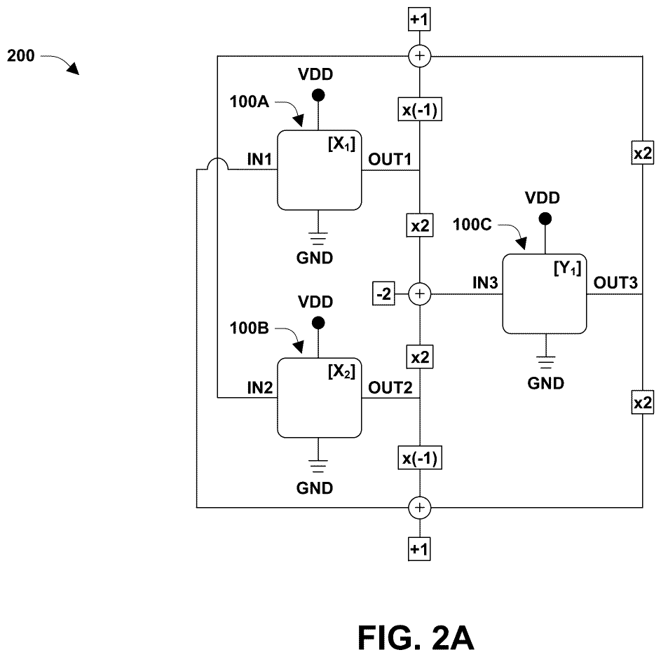

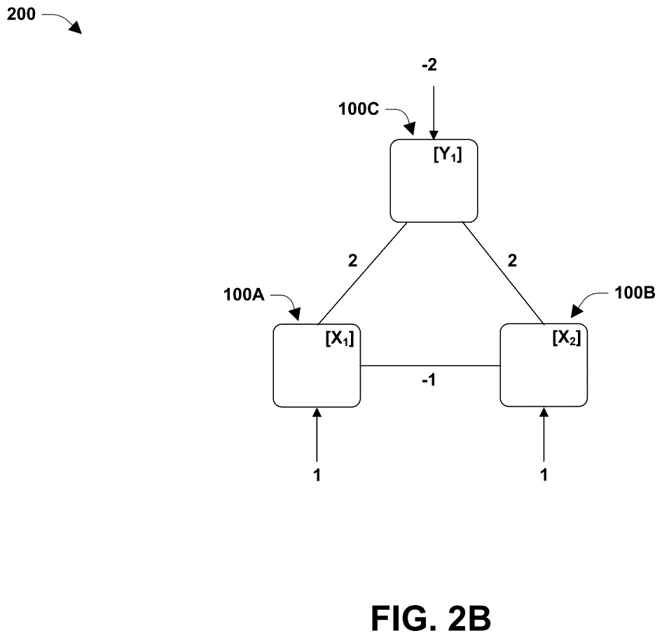

FIGS. 2A and 2B are diagrams illustrating a probabilistic logic device 200, in accordance with some embodiments. FIG. 2A illustrates a schematic view of the probabilistic logic device 200. FIG. 2B illustrates a diagrammatic view of the probabilistic logic device 200.

The probabilistic logic device 200 includes at least three p-bit devices 100A, 100B, 100C, which may be the p-bit device 100 or may be similar in most respects to the p-bit device 100. The first p-bit device 100A ([X₁]) includes a first input IN1 and a first output OUT1. The second p-bit device 100B ([X₂]) includes a second input IN2 and a second output OUT2. The third p-bit device 100C ([Y₁]) includes a third input IN3 and a third output OUT3. The first p-bit device 100A receives a first input signal at the first input IN1 and generates a first output signal at the first output OUT1. The second p-bit device 100B receives a second input signal at the second input IN2 and generates a second output signal at the second output OUT2. The third p-bit device 100C receives a third input signal at the third input IN3 and generates a third output signal at the third output OUT3. Interconnections between the p-bit devices 100A, 100B, 100C and weightings of input signals therein can be selected to select a function of the probabilistic logic device 200. In some embodiments, the probabilistic logic device 200 is a probabilistic AND gate or “reverse AND gate.”

In some embodiments, the first p-bit device 100A receives the first input signal that is a sum of: (i) twice the third output signal, (ii) negative one times the second output signal and (iii) positive one. In some embodiments, the second p-bit device 100B receives the second input signal that is a sum of: (i) twice the third output signal, (ii) negative one times the first output signal and (iii) positive one. In some embodiments, the third p-bit device 100C receives the third input signal that is a sum of: (i) twice the first output signal, (ii) twice the second output signal and (iii) negative two.

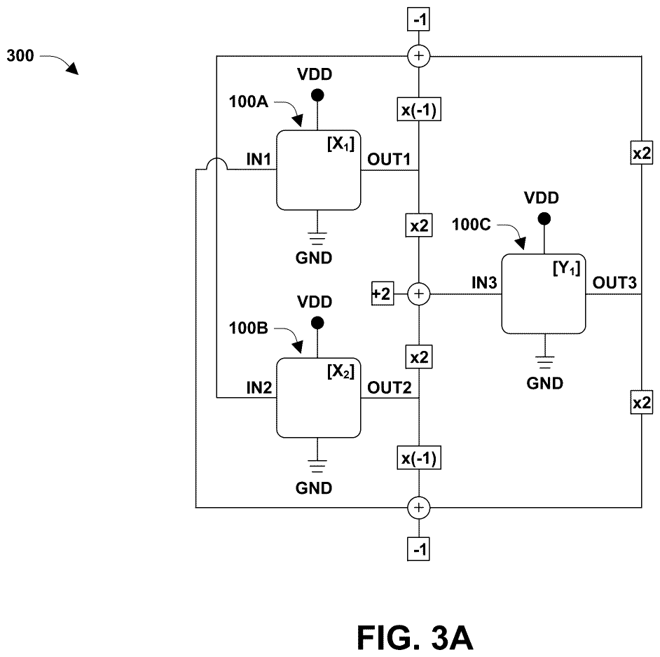

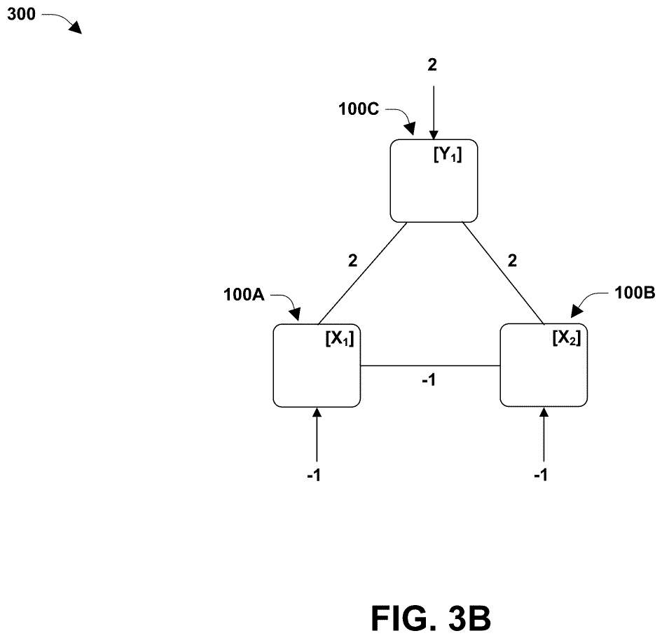

FIGS. 3A and 3B are diagrams illustrating a probabilistic logic device 300, in accordance with some embodiments. FIG. 3A illustrates a schematic view of the probabilistic logic device 300. FIG. 3B illustrates a diagrammatic view of the probabilistic logic device 300. The probabilistic logic device 300 is similar in most respects to the probabilistic logic device 200. Interconnections between the p-bit devices 100A, 100B, 100C and weightings of input signals therein can be selected to select a function of the probabilistic logic device 300. In some embodiments, the probabilistic logic device 300 is a probabilistic OR gate or “reverse OR gate.”

In some embodiments, the first p-bit device 100A receives the first input signal that is a sum of: (i) twice the third output signal, (ii) negative one times the second output signal and (iii) negative one. In some embodiments, the second p-bit device 100B receives the second input signal that is a sum of: (i) twice the third output signal, (ii) negative one times the first output signal and (iii) negative one. In some embodiments, the third p-bit device 100C receives the third input signal that is a sum of: (i) twice the first output signal, (ii) twice the second output signal and (iii) positive two.

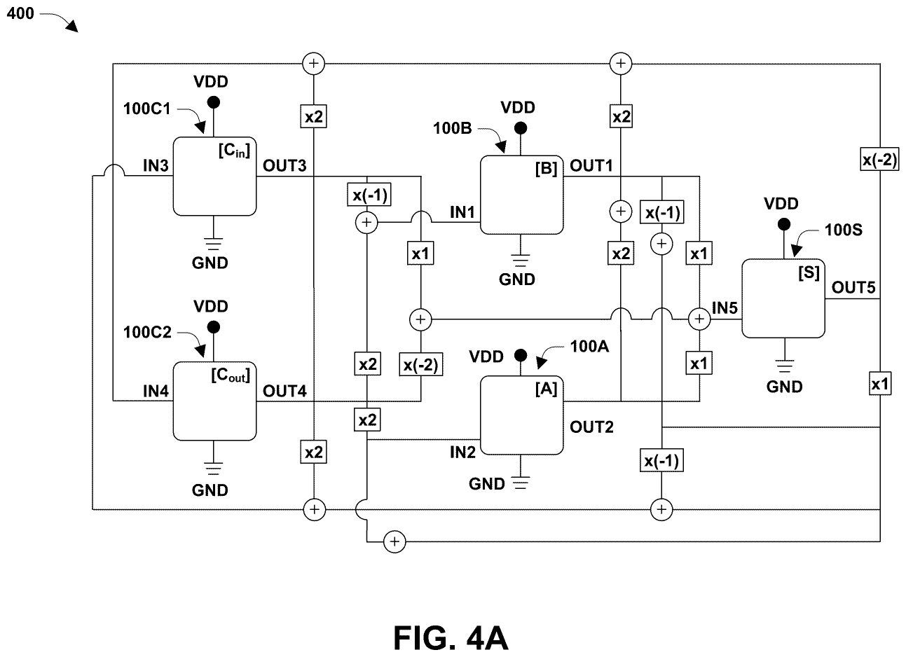

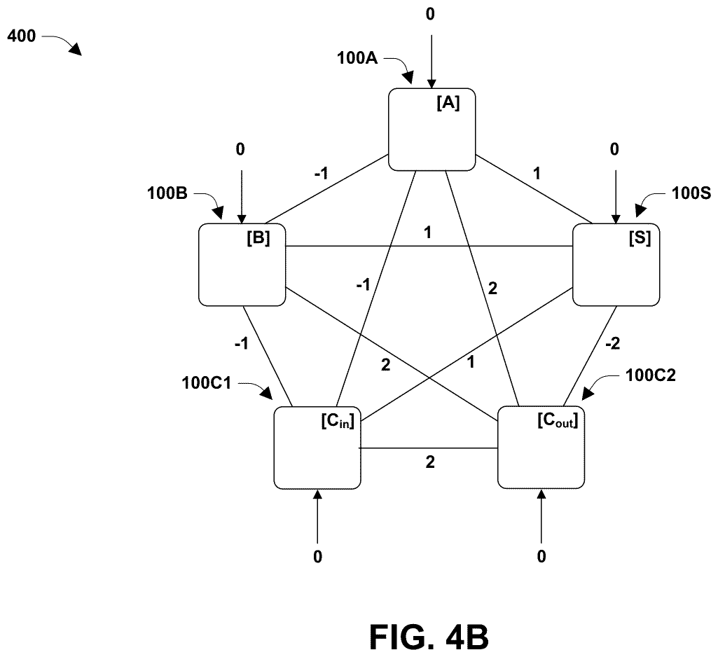

FIGS. 4A and 4B are diagrams illustrating a probabilistic logic device 400, in accordance with some embodiments. FIG. 4A illustrates a schematic view of the probabilistic logic device 400. FIG. 4B illustrates a diagrammatic view of the probabilistic logic device 400. The probabilistic logic device 400 is similar in some respects to the probabilistic logic devices 200, 300. Interconnections between p-bit devices 100A ([A]), 100B ([B]), 100C1 ([Cᵢₙ]), 100C2 ([Cₒᵤₜ]) and 100S ([S]) and weightings of input signals therein can be selected to select a function of the probabilistic logic device 400. In some embodiments, the probabilistic logic device 400 is a probabilistic full adder or “reverse full adder.”

The first p-bit device 100A receives a first input signal at the first input IN1 and generates a first output signal at the first output OUT1. The second p-bit device 100B receives a second input signal at the second input IN2 and generates a second output signal at the second output OUT2. The third p-bit device 100C1 receives a third input signal at the third input IN3 and generates a third output signal at the third output OUT3. The fourth p-bit device 100C2 receives a fourth input signal at the fourth input IN4 and generates a fourth output signal at the third output OUT4. The fifth p-bit device 100S receives a fifth input signal at the fifth input IN5 and generates a fifth output signal at the fifth output OUT5.

In some embodiments, the first p-bit device 100A receives the first input signal that is a sum of: (i) negative one times the second output signal, (ii) negative one times the third output signal, (iii) two times the fourth output signal, and (iv) one times the fifth output signal. In some embodiments, the second p-bit device 100B receives the second input signal that is a sum of: (i) negative one times the first output signal, (ii) negative one times the third output signal, (iii) two times the fourth output signal, and (iv) one times the fifth output signal. In some embodiments, the third p-bit device 100C1 receives the third input signal that is a sum of: (i) negative one times the first output signal, (ii) negative one times the second output signal, (iii) two times the fourth output signal and (iii) one times the fifth output signal. In some embodiments, the fourth p-bit device 100C2 receives the fourth input signal that is a sum of: (i) two times the first output signal, (ii) two times the second output signal, (iii) two times the third output signal and (iii) negative two times the fifth output signal. In some embodiments, the fifth p-bit device 100S receives the fifth input signal that is a sum of: (i) one times the first output signal, (ii) one times the second output signal, (iii) one times the third output signal and (iii) negative two times the fourth output signal.

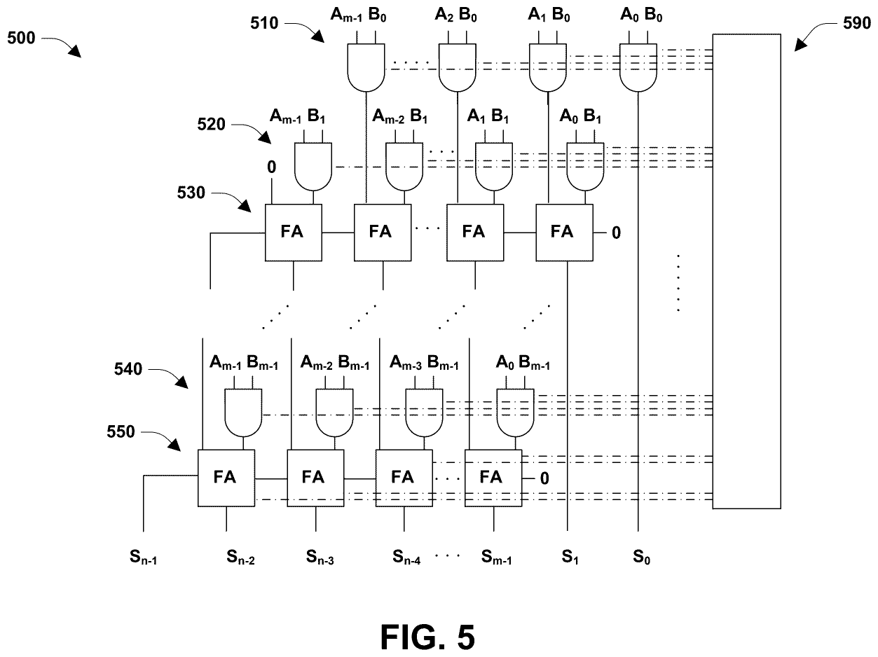

FIG. 5 is a diagram illustrating a probabilistic logic device 500 (or “system 500”), in accordance with some embodiments. In some embodiments, the probabilistic logic device 500, in operation, generates integer factor inputs associated with a clamped product output. For example, in the probabilistic logic device 500, a first factor input A[m-1:0] and a second factor input B[m-1:0] are determined which are associated with a product output S[n-1:0], where “m” is an integer that exceeds two (e.g., 4, 8, 16 or the like) and “n” is an integer that exceeds four (e.g., 8, 16, 32 or the like). In some embodiments, “n” is twice “m.”

The probabilistic logic device 500 includes a first row of first logic gates 510, a second row of second logic gates 520 and a first row of logic circuits 530. In some embodiments, the probabilistic logic device 500 includes an additional at least one row of third logic gates 540 and an additional at least one row of second logic circuits 550. In some embodiments, each of the first logic gates 510 is a reverse AND gate, which may be or include the probabilistic logic device 200. In some embodiments, each of the second logic gates 520 is a reverse AND gate, which may be or include the probabilistic logic device 200. In some embodiments, each of the first logic circuits 530 is a reverse full adder, which may be or include the probabilistic logic device 400. In some embodiments, each of the third logic gates 540 is a reverse AND gate, which may be or include the probabilistic logic device 200. In some embodiments, each of the second logic circuits 550 is a reverse full adder, which may be or include the probabilistic logic device 400.

Each of the first logic circuits 530 receives as an input signal either: (i) two respective outputs of the first logic gates 510 and the second logic gates 520 or (ii) one of the outputs of the second logic gates 520 and zero. Each of the second logic circuits 550 receives as an input signal one respective output of the third logic gates 540 and one respective output of a preceding logic circuit, such as the respective first logic circuit 530. Each of the second logic circuits 550 outputs one or two bits of the product output S[n-1:0]. In some embodiments, one of the first logic circuits 530 outputs a bit of the product output S[n-1:0] and one of the first logic gates 510 outputs a bit of the product output S[n-1:0].

A controller 590 is in electrical communication with each of the first logic gates 510, the second logic gates 520, the first logic circuits 530, the third logic gates 540, and the second logic circuits 550. In some embodiments, the controller 590 outputs output voltage signals to respective p-bit devices of the first logic gates 510, the second logic gates 520, the first logic circuits 530, the third logic gates 540 and the second logic circuits 550. For example, the controller 590 can output to the p-bit devices one or more of the output voltage signals including: (i) the first voltage signal Vdpr, (ii) the second voltage signal Vdsr, (iii) the first gate voltage signal Vgpr and (iv) the second gate voltage signal Vgsr. In some embodiments, the controller 590 outputs the output voltage signals to the respective p-bit devices in response to receiving one or more input voltage signals received or read from the respective p-bit devices, such as the MTJ voltage associated with each p-bit device of the first logic gates 510, the second logic gates 520, the first logic circuits 530, the third logic gates 540 and the second logic circuits 550.

In operation, the controller 590 may generate output voltages associated with a first MTJ of a first p-bit device and a second MTJ of a second p-bit device. The output voltages may be used to select a first value of a first variable resistor of the first p-bit device and to select a second value of a second variable resistor of the second p-bit device. The first value and the second value may be selected based on a first MTJ voltage of the first MTJ and a second MTJ voltage of the second MTJ. The controller 590 can select the first value of the first variable resistor, where the first value is associated with a first reference voltage of the first p-bit device. The controller 590 can select the second value of the second variable resistor, where the second value is associated with a second reference voltage of the second p-bit device. The second value can be different than the first value. It should be understood that “being different” includes the meaning that electrical resistances of the first and second variable resistors are different than each other. For example, the first value may be 100 ohms and the second value may be greater than or less than 100 ohms, such as 90 ohms, 110 ohms, or another suitable value.

In some embodiments, the controller 590 may determine an upper MTJ voltage associated with the first MTJ of the first p-bit device operating in a first state (e.g., a parallel state) and a lower MTJ voltage associated with the first MTJ of the first p-bit device operating in a second state (e.g., an antiparallel state). Then, the controller 590 may select a value of the variable resistor device of the first p-bit device, such that the reference voltage is between the upper MTJ voltage and the lower MTJ voltage. The process just described may be repeated for each p-bit device of the probabilistic logic device 500 to select the respective value of the variable resistor device of the respective p-bit device, such that the reference voltage thereof is between the upper and lower MTJ voltages of the respective p-bit device.

In some embodiments, the controller 590 determines an MTJ voltage associated with each p-bit device included in the probabilistic logic device 500. For example, each of the reverse AND gates may include three MTJs (e.g., three p-bit devices) and each of the reverse full adders may include five MTJs (e.g., five p-bit devices). Based on the MTJ voltages associated with the p-bit devices included in the probabilistic logic device 500, the controller 590 may determine an expected MTJ voltage. In some embodiments, the expected MTJ voltage is an average MTJ voltage that is equal to an average of magnitudes of the MTJ voltages. For example, over about one thousand MTJs, for an input voltage Vin of about 0.7 Volts (V), the average MTJ voltage Vm may be about 0.2V to about 0.25V. In this example, the expected MTJ voltage may be about 0.23V.

In response to the first MTJ voltage associated with the first MTJ of the first p-bit device exceeding the expected MTJ voltage, the controller 590 can increase the first reference voltage Vref of the first p-bit device by reducing the first value of the first variable resistor of the first p-bit device. In response to the first MTJ voltage associated with the first MTJ of the first p-bit device not exceeding the expected MTJ voltage, the controller 590 can decrease the first reference voltage Vref of the first p-bit device by increasing the first value of the first variable resistor of the first p-bit device. Increasing or reducing the first value of the first variable resistor may be performed by any of the methods described with reference to FIGS. 1A-1G. A similar process as just described can be performed to select the second reference voltage Vref of the second p-bit device by determining whether the second MTJ voltage associated with the second MTJ of the second p-bit device exceeds or does not exceed the expected MTJ voltage. It should be understood that some MTJ voltages of the probabilistic logic device 500 will exceed the expected MTJ voltage, while other MTJ voltages of the probabilistic logic device 500 will not exceed the expected MTJ voltage. As such, each variable resistor of each p-bit device of the probabilistic logic device 500 may have value that is selected by the controller 590 based on whether the MTJ voltage of the respective p-bit device exceeds or does not exceed the expected MTJ voltage.

In some embodiments, determining the MTJ voltages and selecting the respective values of the associated variable resistors is performed per a schedule. For example, the selection of the values may be performed only once, such as prior to packaging the IC device that includes the probabilistic logic device 500. In another example, the selection of the values may be performed periodically over the lifetime of the IC device, such as once per day, once per week, once per month, or another suitable interval. In another example, the selection of the values may be performed after a selected number of operations of the probabilistic logic device 500, such as once every hundred operations, once every thousand operations, once every million operations, or another suitable number.

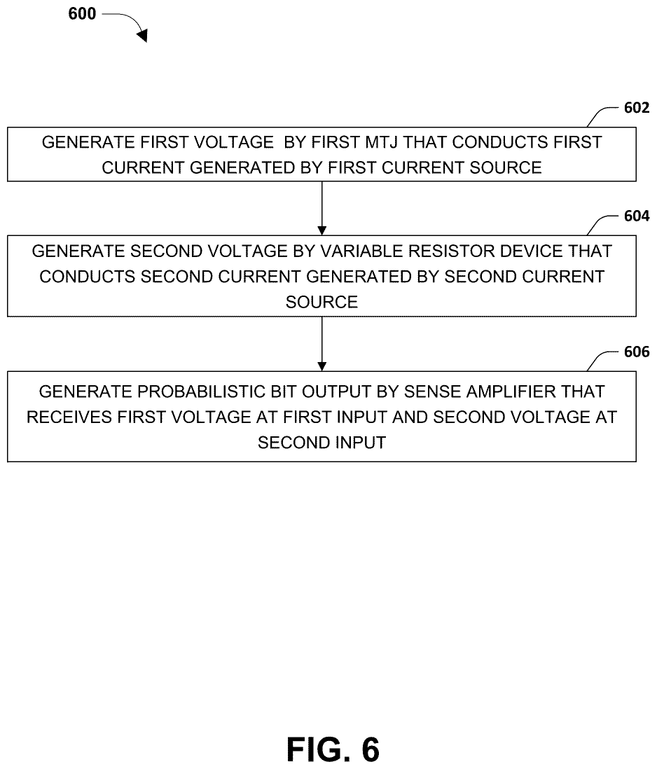

FIG. 6 illustrates a method 600 of generating a probabilistic output, in accordance with some embodiments.

At 602, the method 600 includes generating a first voltage by a first magnetic tunnel junction (MTJ) that conducts a first current generated by a first current source.

At 604, the method 600 includes generating a second voltage by a variable resistor device that conducts a second current generated by a second current source.

At 606, the method 600 includes generating a probabilistic bit output voltage by a sense amplifier that receives the first voltage at a first input thereof and the second voltage at a second input thereof. In some embodiments, generating the probabilistic bit output voltage by the sense amplifier includes generating the probabilistic bit output voltage by the sense amplifier that is positioned in a device layer, the first MTJ and the variable resistor device (e.g., a second MTJ) being positioned in an interconnect layer overlying the device layer.

The method 600 can include: determining a first MTJ voltage associated with the first MTJ operating in a first state (e.g., a parallel state); determining a second MTJ voltage associated with the first MTJ operating in a second state (e.g., an antiparallel state); and selecting a value of the variable resistor device associated with the second voltage being between the first MTJ voltage and the second MTJ voltage. In some embodiments, selecting the value of the variable resistor device includes selecting a first voltage signal applied to a first variable resistor of the variable resistor device. In some embodiments, selecting the value of the variable resistor device includes selecting a second voltage signal applied to a second variable resistor of the variable resistor device, the second variable resistor being in series with the first variable resistor. In some embodiments, selecting the second voltage signal includes selecting the second voltage signal applied to a second MTJ, the second MTJ having different shape than that of the first MTJ.

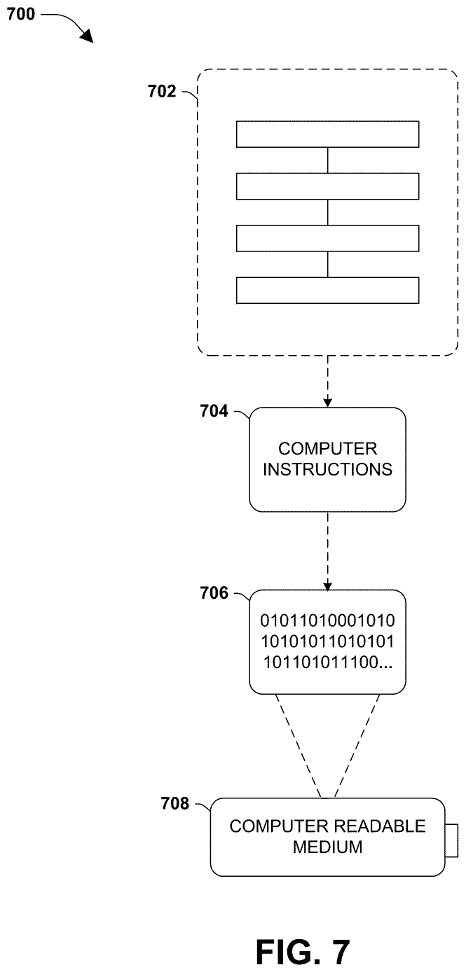

One or more embodiments involve a computer-readable medium comprising processor-executable instructions configured to implement one or more of the techniques presented herein. An exemplary computer-readable medium is illustrated in FIG. 7, wherein the embodiment 700 comprises a computer-readable medium 708 (e.g., a CD-R, DVD-R, flash drive, a platter of a hard disk drive, etc.), on which is encoded computer-readable data 706. This computer-readable data 706 in turn comprises a set of processor-executable computer instructions 704 configured to implement one or more of the principles set forth herein when executed by a processor. In some embodiments 700, the processor-executable computer instructions 704 are configured to implement a method 702, such as at least some of the aforementioned method(s) when executed by a processor. In some embodiments, the processor-executable computer instructions 704 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a device is provided. The device includes: a sense amplifier having a first input, a second input, and an output. The sense amplifier, in operation: receives a first voltage at the first input; receives a second voltage at the second input; and generates a probabilistic output voltage at the output. The device includes: a first voltage generator including a first magnetic tunnel junction, the first voltage generator, in operation, generating the first voltage; and a second voltage generator including a variable resistor, the second voltage generator, in operation, generating the second voltage.

In some embodiments, a system is provided. The system includes a first probabilistic bit device that includes: a first magnetic tunnel junction (MTJ); and a first variable resistor. The system includes a second probabilistic bit device that includes: a second MTJ; and a second variable resistor. The system includes a controller which, in operation: selects a first value of the first variable resistor, the first value being associated with a first reference voltage of the first probabilistic bit device; and selects a second value of the second variable resistor, the second value being associated with a second reference voltage of the second probabilistic bit device, the second value being different than the first value.

In some embodiments, a method is provided. The method includes: generating a first voltage by a first magnetic tunnel junction (MTJ) that conducts a first current generated by a first current source; generating a second voltage by a variable resistor that conducts a second current generated by a second current source; and generating a probabilistic bit output voltage by a sense amplifier that receives the first voltage at a first input thereof and the second voltage at a second input thereof.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A device, comprising:
a sense amplifier having a first input, a second input, and an output, the sense amplifier, in operation:
receiving a first voltage at the first input;
receiving a second voltage at the second input; and
generating a probabilistic output voltage at the output;
a first voltage generator including a first magnetic tunnel junction, the first voltage generator, in operation, generating the first voltage; and
a second voltage generator including a variable resistor, the second voltage generator, in operation, generating the second voltage.

2. The device of claim 1, wherein the variable resistor includes:
a first resistor that has a fixed resistance; and
a second resistor that has a first variable resistance.

3. The device of claim 2, wherein the variable resistor includes a third resistor that has a second variable resistance.

4. The device of claim 3, wherein, in operation, the first variable resistance and the second variable resistance are selected via a third voltage between the second resistor and the third resistor.

5. The device of claim 1, wherein the variable resistor includes a second magnetic tunnel junction that has elliptical profile.

6. The device of claim 5, wherein a ratio of first radius over second radius of the second magnetic tunnel junction is in a range of about 2 to about 3.

7. The device of claim 6, wherein the first magnetic tunnel junction has circular profile having radius in a range of about 10 nanometers to about 50 nanometers.

8. A system, comprising:
a first probabilistic bit device including:
a first magnetic tunnel junction (MTJ); and
a first variable resistor;
a second probabilistic bit device including:
a second MTJ; and
a second variable resistor; and
a controller which, in operation:
selects a first value of the first variable resistor, the first value being associated with a first reference voltage of the first probabilistic bit device; and
selects a second value of the second variable resistor, the second value being associated with a second reference voltage of the second probabilistic bit device, the second value being different than the first value.

9. The system of claim 8, comprising:
a probabilistic logic gate that includes the first probabilistic bit device and the second probabilistic bit device.

10. The system of claim 8, comprising:
a first probabilistic logic gate that includes the first probabilistic bit device; and
a second probabilistic logic gate that includes the second probabilistic bit device.

11. The system of claim 8, comprising:
a probabilistic full adder that includes the first probabilistic bit device and the second probabilistic bit device.

12. The system of claim 8, wherein:
the controller, in operation:
determines a first MTJ voltage associated with the first MTJ; and
determines a second MTJ voltage associated with the second MTJ; and
the first reference voltage has a level that is between those of the first MTJ voltage and the second MTJ voltage.

13. The system of claim 8, wherein:
the first variable resistor includes a fixed resistor and a variable resistor; and
the controller, in operation, selects the first value by selecting a first voltage applied to the variable resistor.

14. The system of claim 13, wherein:
the first variable resistor includes a second variable resistor in series with the variable resistor; and
the controller, in operation, selects the first value by selecting a second voltage applied to the second variable resistor.

15. A method, comprising:
generating a first voltage by a first magnetic tunnel junction (MTJ) that conducts a first current generated by a first current source;
generating a second voltage by a variable resistor device that conducts a second current generated by a second current source; and
generating a probabilistic bit output voltage by a sense amplifier that receives the first voltage at a first input thereof and the second voltage at a second input thereof.

16. The method of claim 15, comprising:
determining a first MTJ voltage associated with the first MTJ operating in a first state;
determining a second MTJ voltage associated with the first MTJ operating in a second state; and
selecting a value of the variable resistor device associated with the second voltage being between the first MTJ voltage and the second MTJ voltage.

17. The method of claim 16, wherein:
selecting the value of the variable resistor device includes selecting a first voltage signal applied to a first variable resistor of the variable resistor device.

18. The method of claim 17, wherein:
selecting the value of the variable resistor device includes selecting a second voltage signal applied to a second variable resistor of the variable resistor device, the second variable resistor being in series with the first variable resistor.

19. The method of claim 18, wherein:
selecting the second voltage signal includes selecting the second voltage signal applied to a second MTJ, the second MTJ having different shape than that of the first MTJ.

20. The method of claim 19, wherein:
generating the probabilistic bit output voltage by the sense amplifier includes generating the probabilistic bit output voltage by the sense amplifier that is positioned in a device layer, the first MTJ and the second MTJ being positioned in an interconnect layer overlying the device layer.
